(19) United States
(12) Patent Application Publication
(10) Pub. No.: US 2024/0178296 A1
(43) Pub. Date: May 30, 2024

(54) SEMICONDUCTOR DEVICE AND METHOD FOR MANUFACTURING THE SAME

(71) Applicant: Dynax Semiconductor, Inc., Suzhou (CN)

(72) Inventor: Qifeng LV, Suzhou (CN)

(73) Assignee: Dynax Semiconductor, Inc., Suzhou (CN)

(21) Appl. No.: 18/436,304

(22) Filed: Feb. 8, 2024

Related U.S. Application Data
(63) Continuation of application No. PCT/CN2022/120978, filed on Sep. 23, 2022.

(30) Foreign Application Priority Data
Sep. 24, 2021 (CN) 202111122149.3

(51) Int. Cl. H01L 29/45; H01L 29/417; H01L 29/66; H01L 29/778

(52) U.S. Cl. CPC H01L 29/45; H01L 29/41775; H01L 29/66431; H01L 29/778

(57) ABSTRACT

A semiconductor device includes an active region; a substrate; an epitaxial structure; an electrode structure, and the electrode structure including a plurality of ohmic contact electrodes; a first dielectric layer; an electrode connection line, the electrode connection line including an ohmic contact electrode connection line, and the ohmic contact electrode connection line being electrically connected to the ohmic contact electrode; an second dielectric layer; an electrode bonding pad, the electrode bonding pad including an ohmic contact electrode bonding pad, the ohmic contact electrode bonding pad being electrically connected to the ohmic contact electrode connection line, and at least a part of the ohmic contact electrode bonding pad being located in the active region, reducing a parasitic capacitance between the ohmic contact electrode bonding pad and the substrate, and further satisfying high requirements on an input capacitance and an output capacitance of the semiconductor device.

### CROSS-REFERENCE TO RELATED APPLICATIONS

The present application is a continuation of International Application No. PCT/CN2022/120978, filed on Sep. 23, 2022, which claims priority to Chinese Patent Application 202111122149.3, filed on Sep. 24, 2021. All of the aforementioned applications are incorporated herein by reference in their entireties.

### TECHNICAL FIELD

The present application relates to the field of semiconductor technologies, and in particular, to a semiconductor device and a method for manufacturing the same.

### BACKGROUND

Semiconductor material gallium nitride has become a hot spot of current research due to its characteristics such as a large band gap, a high electron saturation drift velocity, high breakdown strength, a good heat conduction performance. In an aspect of electronic devices, compared with silicon and gallium arsenide, gallium nitride materials are more suitable for manufacturing devices with high-temperature, high-frequency, high-voltage and high-power, and therefore, gallium nitride-based electronic devices have great application prospects.

An existing gallium nitride-based device is mainly based on a high electron mobility transistor (HEMT) formed by a relatively strong two-dimensional electron gas (2DEG) in an AlGaN/GaN heterojunction structure. With development of technologies, requirements for an input capacitance and an output capacitance of a gallium nitride-based device in an industry are increasing. Therefore, research of a method for reducing a parasitic capacitance in a device is of great importance.

### SUMMARY

Embodiments of the present application provide a semiconductor device and a method for manufacturing the same, so as to reduce a parasitic capacitance in a device, satisfying high requirements on an input capacitance and an output capacitance of a semiconductor device.

According to a first aspect, embodiments of the present application provide a semiconductor device, which includes an active region, and further includes a substrate, an epitaxial structure, an electrode structure, a first dielectric layer, an electrode connection line, a second dielectric layer and an electrode bonding pad.

The epitaxial structure is located on a side of the substrate, and a two-dimensional electron gas is formed in the epitaxial structure located in the active region. The electrode structure is located on a side, away from the substrate, of the epitaxial structure and located in the active region, and the electrode structure includes a plurality of ohmic contact electrodes. The first dielectric layer is located on a side, away from the substrate, of the electrode structure, and the electrode structure is covered by the first dielectric layer. The electrode connection line is located on a side, away from the substrate, of the first dielectric layer, the electrode connection line includes an ohmic contact electrode connection line, and the ohmic contact electrode connection line is electrically connected to the plurality of ohmic contact electrodes. The second dielectric layer is located on a side, away from the substrate, of the electrode connection line, and the electrode connection line is covered by the second dielectric layer. The electrode bonding pad is located on a side, away from the substrate, of the second dielectric layer, the electrode bonding pad includes an ohmic contact electrode bonding pad, the ohmic contact electrode bonding pad is electrically connected to the ohmic contact electrode connection line, and at least a part of the ohmic contact electrode bonding pad is located in the active region.

Optionally, the plurality of ohmic contact electrodes include at least one source electrode and at least one drain electrode.

The ohmic contact electrode connection line includes a source connection line and a drain connection line, the source connection line is electrically connected to the at least one source electrode, and the drain connection line is electrically connected to the at least one drain electrode.

The ohmic contact electrode bonding pad includes a source bonding pad and a drain bonding pad, the source bonding pad is electrically connected to the source connection line, and the drain bonding pad is electrically connected to the drain connection line.

On a plane where the substrate is located, a vertical projection of the source connection line is located outside a vertical projection of the drain connection line.

Optionally, the at least one source electrode comprises a plurality of source electrodes, the at least one drain electrode comprises a plurality of drain electrodes, the active region is provided with the plurality of source electrodes and the plurality of drain electrodes, the plurality of source electrodes are arranged along a first direction, each of the plurality of source electrodes extends along a second direction, the plurality of drain electrodes are arranged along the first direction, each of the plurality of drain electrodes extends along the second direction, and the first direction and the second direction intersect and are both parallel to the plane where the substrate is located.

The source connection line includes a plurality of first source connection line segments and a second source connection line segment, the plurality of first source connection line segments are electrically connected to the plurality of source electrodes, and the second source connection line segment is electrically connected to the plurality of first source connection line segments.

The drain connection line includes a plurality of first drain connection line segments and a second drain connection line segment, the plurality of first drain connection line segments are electrically connected to the plurality of drain electrodes, and the second drain connection line segment is electrically connected to the plurality of first drain connection line segments.

The active region comprises a plurality of active region groups sequentially disposed along the second direction, and each of the plurality of active region groups comprises a first active region and a second active region disposed along the second direction; and along the second direction, each of the plurality of first source connection line segments and each of the plurality of first drain connection line segments are located on two opposite sides of one of the first active region or the second active region in a same active region group.

Along the first direction, the second source connection line segment and the second drain connection line segment are located on two opposite sides of the plurality of active region groups.

Optionally, the active region includes a plurality of active region groups sequentially disposed along the second direction, and each of the plurality of active region groups includes a first active region and a second active region disposed along the second direction.

Each of the plurality of first source connection line segments is located between the first active region and the second active region in a same active region group, the plurality of source electrodes in the first active region and the second active region in a same active region group are all electrically connected to the first source connection line segment, and in a same active region group, the plurality of drain electrodes in the first active region and the plurality of drain electrodes in the second active region are electrically connected to different first drain connection line segments, respectively; and each of the plurality of first drain connection line segments is located between the first active region in one active region group and the second active region in another active region group disposed adjacently to the one active region group along the second direction, the plurality of drain electrodes in the first active region in one active region group and the second active region in another active region group disposed adjacently to the one active region group along the second direction are all electrically connected to the first drain connection line segment, and the plurality of source electrodes in the first active region in one active region group and the plurality of source electrodes in the second active region in another active region group disposed adjacently to the one active region group along the second direction are electrically connected to different first source connection line segments, respectively.

Or, each of the plurality of first drain connection line segments is located between the first active region and the second active region in a same active region group, the plurality of drain electrodes in the first active region and the second active region in a same active region group are all electrically connected to the first drain connection line segment, and in a same active region group, the plurality of source electrodes in the first active region and the plurality of source electrodes in the second active region are electrically connected to different first source connection line segments, respectively; and each of the plurality of first source connection line segments is located between the first active region in one active region group and the second active region in another active region group disposed adjacently to the one active region group along the second direction, the plurality of source electrodes in the first active region in one active region group and the second active region in another active region group disposed adjacently to the one active region group along the second direction are all electrically connected to the first source connection line segment, and the plurality of drain electrodes in the first active region in one active region group and the plurality of drain electrodes in the second active region in another active region group disposed adjacently to the one active region group along the second direction are electrically connected to different first drain connection line segments, respectively.

Optionally, the semiconductor device further includes an inactive region surrounding the active region.

Along the second direction, each of the plurality of first source connection line segments and each of the plurality of first drain connection line segments are located in the inactive region on two sides of one of the first active region or the second active region in a same active region group.

Along the first direction, the second source connection line segment and the second drain connection line segment are located in the inactive region on two sides of the plurality of active region groups.

Optionally, the electrode structure further includes at least one gate electrode.

The electrode connection line further includes a gate connection line, and the gate connection line is electrically connected to the at least one gate electrode.

The electrode bonding pad further includes a gate bonding pad, and the gate bonding pad is electrically connected to the gate connection line.

At least a part of the gate bonding pad is located in the active region.

Optionally, on the plane where the substrate is located, a vertical projection of the gate connection line partially overlaps with the vertical projection of the source connection line, or on the plane where the substrate is located, a vertical projection of the gate connection line partially overlaps with the vertical projection of the drain connection line.

Optionally, the at least one source electrode comprises a plurality of source electrodes, the at least one drain electrode comprises a plurality of drain electrodes, the at least one gate electrode comprises a plurality of gate electrodes, the active region is provided with the plurality of source electrodes, the plurality of gate electrodes and the plurality of drain electrodes, the plurality of source electrodes are arranged along a first direction, each of the plurality of source electrodes extends along a second direction, the plurality of gate electrodes are arranged along the first direction, each of the plurality of gate electrodes extends along the second direction, the plurality of drain electrodes are arranged along the first direction, each of the plurality of drain electrodes extends along the second direction, the gate electrode is located between the source electrode and the drain electrode along the first direction, and the first direction and the second direction intersect and are both parallel to the plane where the substrate is located.

The source connection line includes a plurality of first source connection line segments and a second source connection line segment, the plurality of first source connection line segments are electrically connected to the plurality of source electrodes, and the second source connection line segment is electrically connected to the plurality of first source connection line segments.

The gate connection line includes a plurality of first gate connection line segments and a second gate connection line segment, the plurality of first gate connection line segments are electrically connected to the plurality of gate electrodes, and the second gate connection line segment is electrically connected to the plurality of first gate connection line segments.

The drain connection line includes a plurality of first drain connection line segments and a second drain connection line segment, the plurality of first drain connection line segments are electrically connected to the plurality of drain electrodes, and the second drain connection line segment is electrically connected to the plurality of first drain connection line segments.

Along the second direction, each of the plurality of first source connection line segments and each of the plurality of first gate connection line segments are located on a same side of one of the first active region or the second active region in a same active region group, or along the second direction, each of the plurality of first drain connection line segments and each of the plurality of first gate connection line segments are located on a same side of one of the first active region or the second active region in a same active region group.

Along the first direction, the second source connection line segment and the second gate connection line segment are located on a same side of the plurality of active region groups, or along the first direction, the second drain connection line segment and the second gate connection line segment are located on a same side of the plurality of active region groups.

Optionally, on the plane where the substrate is located, a vertical projection of the gate connection line partially overlaps with the vertical projection of the source connection line, and the gate connection line and the source connection line are disposed in different layers.

Or, on the plane where the substrate is located, a vertical projection of the gate connection line partially overlaps with the vertical projection of the drain connection line, and the gate connection line and the drain connection line are disposed in different layers.

Optionally, the source connection line and the drain connection line are disposed in a same layer.

Optionally, the first dielectric layer includes a first sub-dielectric layer and a second sub-dielectric layer that are stacked, and the first sub-dielectric layer is located on a side, close to the substrate, of the second sub-dielectric layer.

The gate connection line is located on a side, away from the substrate, of the first sub-dielectric layer, and the source connection line and the drain connection line are located on a side, away from the substrate, of the second sub-dielectric layer.

According to a second aspect, embodiments of the present application provide a method for manufacturing a semiconductor device, which is used to manufacture the semiconductor device mentioned above, and the semiconductor device includes an active region.

The method for manufacturing a semiconductor device includes: providing a substrate; preparing an epitaxial structure on a side of the substrate, and a two-dimensional electron gas being formed in the epitaxial structure located in the active region; preparing an electrode structure on a side, away from the substrate, of the epitaxial structure and in the active region, and the electrode structure including a plurality of ohmic contact electrodes; preparing a first dielectric layer on a side, away from the substrate, of the electrode structure, and the electrode structure being covered by the first dielectric layer; preparing an electrode connection line on a side, away from the substrate, of the first dielectric layer, the electrode connection line including an ohmic contact electrode connection line, and the ohmic contact electrode connection line being electrically connected to the plurality of ohmic contact electrodes; preparing a second dielectric layer on a side, away from the substrate, of the electrode connection line, and the electrode connection line being covered by the second dielectric layer; and preparing an electrode bonding pad on a side, away from the substrate, of the electrode connection line, the electrode bonding pad including an ohmic contact electrode bonding pad, the ohmic contact electrode bonding pad being electrically connected to the ohmic contact electrode connection line, and at least a part of the ohmic contact electrode bonding pad being located in the active region.

According to the semiconductor device provided in the embodiments of the present application, an electrical connection between the electrode structure and the electrode bonding pad is realized by means of the electrode connection line, ensuring a flexible arrangement of the electrode bonding pad; furthermore, a position of the electrode connection line is reasonably set, ensuring that a parasitic capacitance between different electrode connection lines may not increase due to the disposal of the electrode connection line. Meanwhile, the at least a part of the ohmic contact electrode bonding pad is disposed in the active region, so that a parasitic capacitance between the at least a part of the ohmic contact electrode bonding pad and the substrate is shielded by the two-dimensional electron gas in a heterojunction structure, reducing the parasitic capacitance between the ohmic contact electrode bonding pad and the substrate, and further satisfying increasingly high requirements on an input capacitance and an output capacitance of a semiconductor device; and the at least a part of the ohmic contact electrode bonding pad is disposed in the active region, so that an area of an inactive area may be greatly reduced, reducing an overall area of a semiconductor device and improving an integration level of a semiconductor device, and further facilitating a miniaturization design of a semiconductor device while reducing a cost of a chip.

### BRIEF DESCRIPTION OF THE DRAWINGS

FIG. 1 is a schematic structural diagram of a semiconductor device according to an embodiment of the present application.

FIG. 2 is a schematic structural diagram of a cross section of the semiconductor device along the section line A-A provided in FIG. 1.

FIG. 3 is a schematic structural diagram of a cross section of the semiconductor device along the section line B-B provided in FIG. 1.

FIG. 4 is a flowchart of a method for manufacturing a semiconductor device according to an embodiment of the present application.

### DETAILED DESCRIPTIONS OF THE EMBODIMENTS

The present application may be further described below with reference to the accompanying drawings and embodiments. It can be understood that the specific embodiments described herein are merely used for explaining the present application, rather than limiting the present application. In addition, it should be noted that, for ease of description, only some rather than all structures related to the present application are shown in the accompanying drawings.

A current research on reducing a parasitic capacitance is mainly focused on reducing a capacitance in an active region, for example, reducing an area of a field plate, increasing a thickness of a medium between the field plate and the 2DEG, using a medium having a relatively small dielectric constant, and the like. However, these methods have two problems: firstly, reducing the area of the field plate may reduce a withstand voltage capability of the device; and secondly, increasing the thickness of the medium between the field plate and the 2DEG and replacing the medium with relatively small electrical constant may make a process more complex, to improve a production cost.

A semiconductor device in related technologies generally includes an active region and an inactive region, a source electrode, a gate electrode, and a drain electrode are disposed in the active region, and an electrode bonding pad, such as a drain bonding pad, is generally disposed in the inactive region. A parasitic capacitance is formed between the drain bonding pad and a substrate in the semiconductor device, which affects an output capacitance and an input capacitance of the semiconductor device; and large amount of area may be occupied by the electrode bonding pad, so that an area of a whole chip is relatively increased, which is disadvantageous for a miniaturization design of the semiconductor device, and is also disadvantageous for reducing manufacturing costs of the chip.

Based on the above technical problems, an embodiment of the present application provides a semiconductor device, which includes a substrate, an epitaxial structure, an electrode structure, a first dielectric layer, an electrode connection line, a second dielectric layer, and an electrode bonding pad. The epitaxial structure is located on a side of the substrate, and a two-dimensional electron gas is formed in the epitaxial structure located in the active region; the electrode structure is located on a side of the substrate and located in the active region, and the electrode structure includes a plurality of ohmic contact electrodes; the first dielectric layer, located on a side, away from the substrate, of the electrode structure, and the electrode structure is covered by the first dielectric layer; the electrode connection line is located on a side, away from the substrate, of the first dielectric layer, the electrode connection line includes an ohmic contact electrode connection line, and the ohmic contact electrode connection line is electrically connected to the ohmic contact electrode; the second dielectric layer is located on a side, away from the substrate, of the electrode connection line, and the electrode connection line is covered by the second dielectric layer; and the electrode bonding pad is located on a side, away from the substrate, of the second dielectric layer. The electrode bonding pad includes an ohmic contact electrode bonding pad, the ohmic contact electrode bonding pad is electrically connected to the ohmic contact electrode connection line, and at least a part of the ohmic contact electrode bonding pad is located in the active region. By adopting the above technical solutions, an electrical connection between the electrode structure and the electrode bonding pad is realized by means of the electrode connection line, ensuring a flexible arrangement of the electrode bonding pad; furthermore, a position of the electrode connection line is reasonably set, ensuring that a parasitic capacitance between different electrode connection lines may not increase due to the disposal of the electrode connection line. Meanwhile, the at least a part of the ohmic contact electrode bonding pad is disposed in the active region, so that a parasitic capacitance between the at least a part of the ohmic contact electrode bonding pad and the substrate is shielded by the two-dimensional electron gas in a heterojunction structure, reducing the parasitic capacitance between the ohmic contact electrode bonding pad and the substrate, and further satisfying increasingly high requirements on an input capacitance and an output capacitance of a semiconductor device; furthermore, the at least a part of the ohmic contact electrode bonding pad is disposed in the active region, so that an area of an inactive area may be greatly reduced, reducing an overall area of a semiconductor device is and improving an integration level of a semiconductor device, and further facilitating a miniaturization design of a semiconductor device is facilitated while reducing a cost of a chip.

The technical solutions in the embodiments of the present application may be clearly and completely described below with reference to the accompanying drawings in the embodiments of the present application. Based on the embodiments in the present application, all other embodiments obtained by a person of ordinary skill in the art without creative efforts shall fall within the protection scope of the present application.

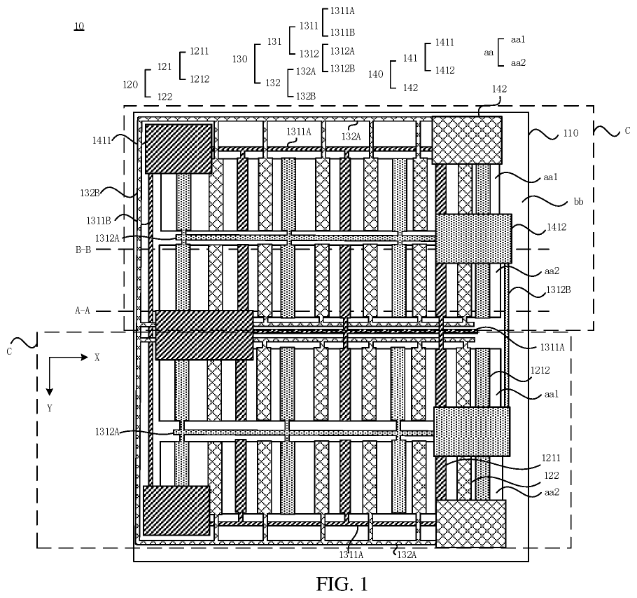

FIG. 1 is a schematic structural diagram of a semiconductor device according to an embodiment of the present application, and FIG. 2 is a schematic structural diagram of a cross section of the semiconductor device along the section line A-A provided in FIG. 1. Referring to FIG. 1 and FIG. 2, the semiconductor device 10 includes an active region aa; and the semiconductor device 10 further includes a substrate 110, an epitaxial structure 150, an electrode structure 120, a first dielectric layer a, an electrode connection line 130, a second dielectric layer b, and an electrode bonding pad 140.

The epitaxial structure 150 is located on a side of the substrate 110, and a two-dimensional electron gas 155 is formed in the epitaxial structure 150 located in the active region aa. The electrode structure 120 is located on a side, away from the substrate 110, of the epitaxial structure 150 and located in the active region aa, and the electrode structure 120 includes a plurality of ohmic contact electrodes 121. The first dielectric layer a is located on a side, away from the substrate 110, of the electrode structure 120, and the electrode structure 120 is covered by the first dielectric layer a. The electrode connection line 130 is located on a side, away from the substrate 110, of the first dielectric layer a, the electrode connection line 130 includes an ohmic contact electrode connection line 131, and the ohmic contact electrode connection line 131 is electrically connected to the ohmic contact electrode 121. The second dielectric layer b is located on a side, away from the substrate 110, of the electrode connection line 130, and the electrode connection line 130 is covered by the second dielectric layer b. The electrode bonding pad 140 is located on a side, away from the substrate 110, of the second dielectric layer b. The electrode bonding pad 140 includes an ohmic contact electrode bonding pad 141, the ohmic contact electrode bonding pad 141 is electrically connected to the ohmic contact electrode connection line 131, and at least a part of the ohmic contact electrode bonding pad 141 is located in the active region aa.

As shown in FIG. 1 and FIG. 2, the semiconductor device 10 includes the active region aa, the active region aa may be understood as a region below which there are two-dimensional electron gases, electrons or holes, and a working state and characteristics of the active region aa are affected by an external circuit, which is an active working region of the semiconductor device. The semiconductor device 10 includes the epitaxial structure 150, the electrode structure 120, the first dielectric layer a, the electrode connection line 130, the second dielectric layer b, and the electrode bonding pad 140 that are sequentially located on the side of the substrate 110. A heterojunction structure is formed in the epitaxial structure 150, and the two-dimensional electron gas 155 is formed in the heterojunction structure located in the active region aa. The electrode connection line 130 is electrically connected to the electrode structure 120 and the electrode bonding pad 140, respectively, and is used for implementing an electrical connection between the electrode structure 120 and the electrode bonding pad 140. The first dielectric layer a is located between the electrode structure 120 and the electrode connection line 130, a correspondingly disposed electrode and the electrode connection line are electrically connected by a via in the first dielectric layer a, and a non-correspondingly disposed electrode and the electrode connection line are electrically insulated by the first dielectric layer a. Similarly, the second dielectric layer b is located between the electrode structure 120 and the electrode connection line 130, a correspondingly disposed electrode connection line is electrically connected to the electrode bonding pad by a via in the second dielectric layer b, and a non-correspondingly disposed electrode connection line and the electrode bonding pad are electrically insulated by the second dielectric layer b.

For example, in some embodiments of the present application, the electrode structure 120 includes the plurality of ohmic contact electrodes 121, and an ohmic contact is formed between the ohmic contact electrodes 121 and the epitaxial structure 150; correspondingly, the electrode connection line 130 includes the ohmic contact electrode connection line 131, and the ohmic contact electrode connection line 131 is electrically connected to the ohmic contact electrode 121; correspondingly, the electrode bonding pad 140 includes the ohmic contact electrode bonding pad 141, and the ohmic contact electrode bonding pad 141 is electrically connected to the ohmic contact electrode connection line 131, so that an electrical connection between the ohmic contact electrode bonding pad 141 and the ohmic contact electrode 121 is realized, to transmit an electrode signal to the ohmic contact electrode 121. Further, unlike a solution of disposing a ohmic contact electrode bonding pad 141 outside an active region aa, in the embodiments of the present application, the at least a part of the ohmic contact electrode bonding pad 141 is creatively located in the active region aa, and the electrical connection between the electrode structure 120 and the electrode bonding pad 140 is realized by the electrode connection line 130, ensuring a flexible arrangement of the electrode bonding pad 140. Further, the at least a part of the ohmic contact electrode bonding pad 141 is disposed in the active region aa, so that a parasitic capacitance between the at least a part of the ohmic contact electrode bonding pad 141 and the substrate 110 is shielded by the two-dimensional electron gas 155 in the heterojunction structure, reducing the parasitic capacitance between the ohmic contact electrode bonding pad 141 and the substrate 110, and further satisfying increasingly high requirements on an input capacitance and an output capacitance of a semiconductor device. Meanwhile, the at least a part of the ohmic contact electrode bonding pad 141 is disposed in the active region aa, so that an area of an inactive area may be greatly reduced, reducing an overall area of a semiconductor device and improving an integration level of a semiconductor device, and further facilitating a miniaturization design of a semiconductor device while reducing a cost of a chip.

Specifically, a material of the substrate 110 may be formed from one or more materials of silicon, sapphire, silicon carbide, gallium arsenide, gallium nitride or diamond, and the like, and may be formed from other materials suitable for growing gallium nitride.

Materials of the first dielectric layer a and the second dielectric layer b may be dielectric materials such as silicon dioxide, silicon nitride, or aluminum oxide, which is used for isolating the electrode structure 120 and the electrode bonding pad 140. A material of the electrode connection line 130 may be conductive metals such as aluminum, nickel, gold, silver, or platinum.

In summary, in the technical solutions of the embodiments of the present application, an electrical connection between the electrode structure and the electrode bonding pad is realized by means of the electrode connection line, ensuring a flexible arrangement of the electrode bonding pad. Further, the at least a part of the ohmic contact electrode bonding pad is disposed in the active region, so that a parasitic capacitance between the at least a part of the ohmic contact electrode bonding pad and the substrate is shielded by the two-dimensional electron gas in the heterojunction structure, reducing the parasitic capacitance between the ohmic contact electrode bonding pad and the substrate, and further satisfying increasingly high requirements on an input capacitance and an output capacitance of a semiconductor device. Meanwhile, the at least a part of the ohmic contact electrode bonding pad is disposed in the active region, so that an area of an inactive region may be greatly reduced, reducing an overall area of a semiconductor device and improving an integration level of a semiconductor device, and further facilitating a miniaturization design of a semiconductor device while reducing a cost of a chip.

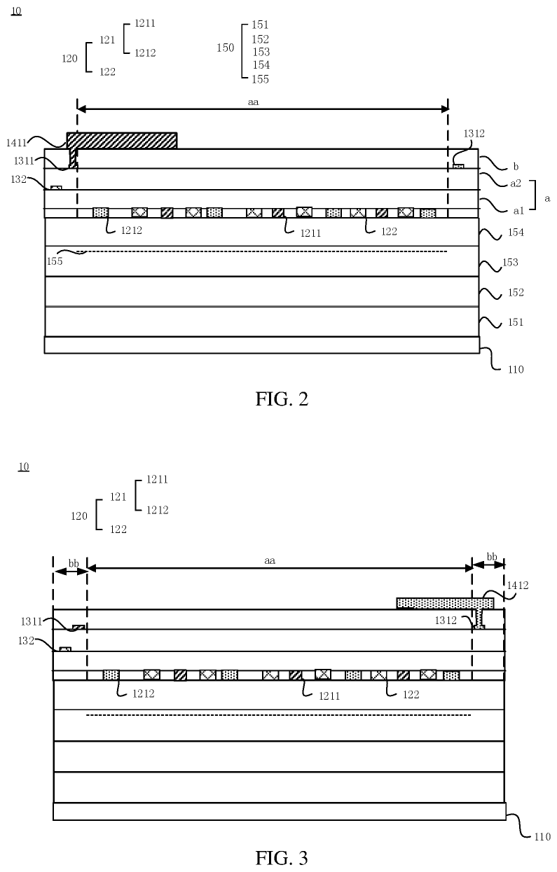

FIG. 3 is a schematic structural diagram of a cross section of the semiconductor device along the section line B-B provided in FIG. 1, referring to FIG. 1 to FIG. 3, the ohmic contact electrode 121 includes a source electrode 1211 and a drain electrode 1212, the ohmic contact electrode connection line 131 includes a source connection line 1311 and a drain connection line 1312, the source connection line 1311 is electrically connected to the source electrode 1211, and the drain connection line 1312 is electrically connected to the drain electrode 1212. The ohmic contact electrode bonding pad 141 includes a source bonding pad 1411 and a drain bonding pad 1412, the source bonding pad 1411 is electrically connected to the source connection line 1311, and the drain bonding pad 1412 is electrically connected to the drain connection line 1312. On a plane where the substrate 110 is located, a vertical projection of the source connection line 1311 does not overlap with a vertical projection of the drain connection line 1312, i.e., on the plane where the substrate 110 is located, the vertical projection of the source connection line 1311 is located outside the vertical projection of the drain connection line 1312. The ohmic contact electrode connection line 131 includes the source connection line 1311 and the drain connection line 1312. The ohmic contact electrode bonding pad 141 includes the source bonding pad 1411 and the drain bonding pad 1412. The source connection line 1311 is electrically connected to the source electrode 1211, and the source bonding pad 1411 is electrically connected to the source connection line 1311, so as to realize a connection between the source electrode 1211 and the source bonding pad 1411. The drain connection line 1312 is electrically connected to the drain electrode 1212, and the drain bonding pad 1412 is electrically connected to the drain connection line 1312, so as to realize a connection between the drain electrode 1212 and the drain bonding pad 1412.

For example, in some embodiments of the present application, at least a part of the source bonding pad 1411 is located in the active region aa, and/or at least a part of the drain bonding pad 1412 is located in the active region aa. Specifically, it may be that all of the source bonding pad 1411 and all of the drain bonding pad 1412 are located in the active region aa, or it may be that the at least a part of the source bonding pad 1411 and the at least a part of the drain bonding pad 1412 are located in the active region aa, or it may be that only the at least a part or all of the source bonding pad 1411 is located in the active region aa, or it may be that only the at least a part or all of the drain bonding pad 1412 is located in the active region aa, which is not limited in the embodiments of the present application. The at least a part of the ohmic contact electrode bonding pad 141 is controlled to dispose in the active region aa, so that a parasitic capacitance between the at least a part of the ohmic contact electrode bonding pad 141 and the substrate 110 is shielded by the two-dimensional electron gas 155, reducing the parasitic capacitance generated between the electrode bonding pad 140 and the substrate 110, and further achieving a relatively high output capacitance and a relatively high input capacitance of the semiconductor device 10.

With continued reference to FIG. 1, on the plane where the substrate 110 is located, the vertical projection of the source connection line 1311 does not overlap with the vertical projection of the drain connection line 1312, i.e., on the plane where the substrate 110 is located, the vertical projection of the source connection line 1311 is located outside the vertical projection of the drain connection line 1312.

FIG. 1 is a top view of the semiconductor device structure, and the source connection line 1311 and the drain connection line 1312 are shown in FIG. 1. On the plane where the substrate 110 is located, the vertical projection of the source connection line 1311 does not overlap with the vertical projection of the drain connection line 1312, so that a parasitic capacitance generated between the source electrode 1211 and the drain electrode 1212 may be avoided.

With continued reference to FIG. 1, the active region aa is provided with a plurality of source electrodes 1211 and a plurality of drain electrodes 1212, the plurality of source electrodes 1211 are arranged along a first direction X, the source electrode 1211 extends along a second direction Y, the plurality of drain electrodes 1212 are arranged along the first direction X, and the drain electrode 1212 extends along the second direction Y; and the first direction X and the second direction Y intersect and are all parallel to the plane where the substrate 110 is located, for example, the first direction X and the second direction Y are perpendicular.

The source connection line 1311 includes a first source connection line segment 1311A and a second source connection line segment 1311B, the first source connection line segment 1311A is electrically connected to the plurality of source electrodes 1211, and the second source connection line segment 1311B is electrically connected to a plurality of first source connection line segments 1311A. The drain connection line 1312 includes a first drain connection line segment 1312A and a second drain connection line segment 1312B, the first drain connection line segment 1312A is electrically connected to the plurality of drain electrodes 1212, and the second drain connection line segment 1312B is electrically connected to a plurality of first drain connection line segments 1312A. Along the second direction Y, the first source connection line segment 1311A and the first drain connection line segment 1312A are located on two opposite sides of a same active region aa. Along the first direction X, the second source connection line segment 1311B and the second drain connection line segment 1312B are located on two opposite sides of a plurality of active regions aa.

The active region aa is provided with the plurality of source electrodes 1211 and the plurality of drain electrodes 1212, the plurality of source electrodes 1211 and the plurality of drain electrodes 1212 are arranged along the first direction X, and the source electrode 1211 and the drain electrode 1212 extend along the second direction Y.

The source connection line 1311 includes the first source connection line segment 1311A and the second source connection line segment 1311B, the first source connection line segment 1311A extends along the first direction X and is electrically connected to the plurality of source electrodes 1211, the second source connection line segment 1311B extends along the second direction Y and is electrically connected to the plurality of first source connection line segments 1311A, and the first source connection line segment 1311A and the second source connection line segment 1311B are located at different positions, so that an effective electrical connection between the source electrode 1211 and the source connection line 1311 may be ensured. Further, the second source connection line segment 1311B may also be used for connecting a plurality of source bonding pads 1411, so as to realize an electrical connection between the source connection line 1311 and the source bonding pad 1411.

The drain connection line 1312 includes the first drain connection line segment 1312A and the second drain connection line segment 1312B, the first drain connection line segment 1312A extends along the first direction X and is electrically connected to the plurality of drain electrodes 1212, the second drain connection line segment 1312B extends along the second direction Y and is electrically connected to the plurality of first drain connection line segments 1312A, and the first drain connection line segment 1312A and the second drain connection line segment 1312B are located at different positions, so that an effective electrical connection between the drain electrode 1212 and the drain electrode connection line 1312 may be ensured. Further, the second drain connection line segment 1312B may also be used for connecting a plurality of drain bonding pads 1412, so as to realize an electrical connection between the drain connection line 1312 and the drain bonding pad 1412.

Further, in order to ensure that on the plane where the substrate 110 is located, the vertical projection of the source connection line 1311 does not overlap with the vertical projection of the drain connection line 1312, along the second direction Y, the first source connection line segment 1311A and the first drain connection line segment 1312A are located on two sides of the active region aa, so as to ensure that the first source connection line segment 1311A and the first drain connection line segment 1312A are not in contact with each other; and along the second direction Y, the second source connection line segment 1311B and the second drain connection line segment 1312B are located on two opposite sides of the plurality of active regions aa, so as to ensure that the second source connection line segment 1311B and the second drain connection line segment 1312B are not in contact with each other, effectively avoiding generation of a parasitic capacitance between the source connection line 1311 and the drain connection line 1312.

With continued reference to FIG. 1, in the semiconductor device 10 provided in the embodiments of the present application, the active region aa includes a plurality of active region groups C sequentially disposed along the second direction Y, and the active region group C includes a first active region aa1 and a second active region aa2 disposed along the second direction Y.

For example, in some embodiments of the present application, the first source connection line segment 1311A is located between the first active region aa1 and the second active region aa2 in a same active region group C, the plurality of source electrodes 1211 in the first active region aa1 and the second active region aa2 in a same active region group C are all electrically connected to the first source connection line segment 1311A, and in a same active region group C, the plurality of drain electrodes 1212 in the first active region aa1 and the plurality of drain electrodes 1212 in the second active region aa2 are electrically connected to different first drain connection line segments 1312A, respectively; and the first drain connection line segment 1312A is located between the first active region aa1 in one active region group C and the second active region aa2 in another active region group C disposed adjacently to the one active region group C along the second direction Y, the plurality of drain electrodes 1212 in the first active region aa1 in one active region group C and the second active region aa2 in another active region group C disposed adjacently to the one active region group C along the second direction Y are all electrically connected to the first drain connection line segment 1312A, and the plurality of source electrodes 1211 in the first active region aa1 in one active region group C and the plurality of source electrodes 1211 in the second active region aa2 in another active region group C disposed adjacently to the one active region group C along the second direction Y are electrically connected to different first source connection line segments 1311A, respectively.

For example, in some other embodiments of the present application, the first drain connection line segment 1312A is located between the first active region aa1 and the second active region aa2 in a same active region group C, the plurality of drain electrodes 1212 in the first active region aa1 and the second active region aa2 in a same active region group C are all electrically connected to the first drain connection line segment 1312A, and in a same active region group C, the plurality of source electrodes 1211 in the first active region aa1 and the plurality of source electrodes 1211 in the second active region aa2 are electrically connected to different first source connection line segments 1311A, respectively; and the first source connection line segment 1311A is located between the first active region aa1 in one active region group C and the second active region aa2 in another active region group C disposed adjacently to the one active region group C along the second direction Y, the plurality of source electrodes 1211 in the first active region aa1 in one active region group C and the second active region aa2 in another active region group C disposed adjacently to the one active region group C along the second direction Y are all electrically connected to the first source connection line segment 1311A, and the plurality of drain electrodes 1212 in the first active region aa1 in one active region group C and the plurality of drain electrodes 1212 in the second active region aa2 in another active region group C disposed adjacently to the one active region group C along the second direction Y are electrically connected to different first drain connection line segments 1312A, respectively.

The active region aa includes a plurality of active region groups C sequentially disposed along the second direction Y, the active region group C includes a plurality of first active regions aa1 and a plurality of second active regions aa2, and as shown in FIG. 1, the plurality of active region groups C are sequentially disposed. Further, taking FIG. 1 as an example, the first drain connection line segment 1312A is located between the first active region aa1 and the second active region aa2 in a same active region group C, and the first source connection line segment 1311A is located between the first active region aa1 in one active region group C and the second active region aa2 in another active region group C disposed adjacently to the one active region group C along the second direction Y.

As shown in FIG. 1, the first drain connection line segment 1312A is located between the first active region aa1 and the second active region aa2 in a same active region group C, the plurality of source electrodes 1211 and the plurality of drain electrodes 1212 are disposed in the first active region aa1 and the second active region aa2 in a same active region group C, and the plurality of drain electrodes 1212 located in a same active region group C are electrically connected to each other by the first drain connection line segment 1312A. The first source connection line segment 1311A and the first drain connection line segment 1312A are located on two sides of a same active region aa and do not overlap, and along the second direction Y, the first source connection line segment 1311A is located on two sides of the first active region aa1 and the second active region aa2 in two adjacent active region groups C along the second direction Y, and therefore, the source electrodes 1211 in the two adjacent active region groups C are electrically connected to the first source connection line segments 1311A at different positions, respectively. The first source connection line segment 1311A and the first drain connection line segment 1312A are arranged at different positions, so as to avoid generation of a parasitic capacitance caused by overlap of the source connection line 1311 and the drain connection line 1312.

With continued reference to FIG. 3, the semiconductor device 10 further includes an inactive region bb, and the active region aa is surrounded by the inactive region bb. Along the second direction Y, the first source connection line segment 1311A and the first drain connection line segment 1312A are located in the inactive region bb on two sides of a same active region aa. Along the first direction X, the second source connection line segment 1311B and the second drain connection line segment 1312B are located in the inactive region bb on two sides of a plurality of active regions aa.

The semiconductor device 10 further includes the inactive region bb, but an operation of the semiconductor device 10 involves participation of the inactive region bb, and a working state of the inactive region bb is not affected by an external circuit. On the plane where the substrate 110 is located, the vertical projection of the source connection line 1311 does not overlap with the vertical projection of the drain connection line 1312, and on the inactive region bb, the vertical projection of the source connection line 1311 does not overlap with the vertical projection of the drain connection line 1312. Specifically, along the second direction Y, the first source connection line segment 1311A and the first drain connection line segment 1312A are located in the inactive region bb on two sides of a same active region aa, and the first source connection line segment 1311A and the first drain connection line segment 1312A are not in contact with each other in the inactive region bb; and along the first direction X, the second source connection line segment 1311B and the second drain connection line segment 1312B are located in the inactive region bb on two sides of the plurality of active regions aa, and the second source connection line segment 1311B and the second drain connection line segment 1312B are not in contact with each other, which may ensure that, on the plane where the substrate 110 is located, the vertical projection of the source connection line 1311 does not overlap with the vertical projection of the drain connection line 1312, avoiding generation of a parasitic capacitance between the source electrode 1211 and the drain electrode 1212.

Referring to FIG. 1 and FIG. 2, the electrode structure 120 further includes a gate electrode 122. The electrode connection line 130 further includes a gate connection line 132, and the gate connection line 132 is electrically connected to the gate electrode 122. The electrode bonding pad 140 further includes a gate bonding pad 142, and the gate bonding pad 142 is electrically connected to the gate connection line 132. At least a part of the gate bonding pad 142 is located in the active region aa.

The electrode structure 120 includes the gate electrode 122, the electrode connection line 130 further includes the gate connection line 132, and the electrode bonding pad 140 further includes the gate bonding pad 142. The gate electrode 122 is made of a conductive metal, and a Schottky contact is formed by the gate electrode 122 and the epitaxial structure 150. The gate connection line 132 is electrically connected to the gate electrode 122, the gate bonding pad 142 is electrically connected to the gate connection line 132, and therefore, the gate electrode 122 is connected to the gate bonding pad 142 through the gate connection line 132. Moreover, the at least a part of the gate bonding pads 142 is located in the active region aa, exemplarily, it may be all of the gate bonding pad 142 is located in the active region aa, or it may also be only a part of the gate bonding pad 142 is located in the active region aa, so that a reduction in an area of the gate bonding pad 142 in the inactive region bb may be ensured, reducing an overall area of the semiconductor device, and further improving an integration level of the semiconductor device.

With continued reference to FIG. 1, on the plane where the substrate 110 is located, a vertical projection of the gate connection line 132 partially overlaps with the vertical projection of the source connection line 1311, or on the plane where the substrate 110 is located, a vertical projection of the gate connection line 132 partially overlaps with the vertical projection of the drain connection line 1312.

In order to reduce a parasitic capacitance between the source electrode 1211 and the drain electrode 1212, it is possible to set that on the plane where the substrate 110 is located, the vertical projection of the source connection line 1311 does not overlap with the vertical projection of the drain connection line 1312. Further, in order to realize a connection relationship between the gate connection line 132 and the gate electrode 122 and a connection relationship between the gate connection line 132 and the gate bonding pad 142, and to ensure a compact size of the semiconductor device, it is possible to set that on the plane where the substrate 110 is located, the vertical projection of the gate connection line 132 partially overlaps with the vertical projection of the source connection line 1311, or on the plane where the substrate 110 is located, the vertical projection of the gate connection line 132 partially overlaps with the vertical projection of the drain connection line 1312. FIG. 1 illustrates only an example that on the plane where the substrate 110 is located, the vertical projection of the gate connection line 132 partially overlaps with the vertical projection of the source connection line 1311.

Optionally, the active region aa is provided with a plurality of source electrodes 1211, a plurality of gate electrodes 122 and a plurality of drain electrodes 1212, the plurality of source electrodes 1211 are arranged along the first direction X, the source electrode 1211 extends along the second direction Y, the plurality of gate electrodes 122 are arranged along the first direction X, the gate electrode 122 extends along the second direction Y, the plurality of drain electrodes 1212 are arranged along the first direction X, the drain electrode 1212 extends along the second direction Y, and the gate electrode 122 is located between the source electrode 1211 and the drain electrode 1212 along the first direction X. The first direction X and the second direction Y intersect and are both parallel to the plane where the substrate 110 is located.

The source connection line 1311 includes a first source connection line segment 1311A and a second source connection line segment 1311B, the first source connection line segment 1311A is electrically connected to the plurality of source electrodes 1211, and the second source connection line segment 1311B is electrically connected to a plurality of first source connection line segments 1311A.

The gate connection line 132 includes a first gate connection line segment 132A and a second gate connection line segment 132B, the first gate connection line segment 132A is electrically connected to the plurality of gate electrodes 122, and the second gate connection line segment 132B is electrically connected to a plurality of first gate connection line segments 132A.

The drain connection line 1312 includes a first drain connection line segment 1312A and a second drain connection line segment 1312B, the first drain connection line segment 1312A is electrically connected to the plurality of drain electrodes 1212, and the second drain connection line segment 1312B is electrically connected to a plurality of first drain connection line segments 1312A.

Along the second direction Y, the first source connection line segment 1311A and the first gate connection line segment 132A are located on a same side of a same active region aa, or the first drain connection line segment 1312A and the first gate connection line segment 132A are located on a same side of a same active region aa.

Along the first direction X, the second source connection line segment 1311B and the second gate connection line segment 132B are located on a same side of a plurality of active regions aa, or the second drain connection line segment 1312B and the second gate connection line segment 132B are located on a same side of a plurality of active regions aa.

The active region aa is further provided with the plurality of gate electrodes 122. As shown in FIG. 1, the plurality of gate electrodes 122 are arranged along the first direction X, and the gate electrode 122 extends along the second direction Y, ensuring that the plurality of gate electrodes 122 are regularly arranged on the active region aa and have a certain length.

The gate connection line 132 includes the first gate connection line segment 132A and the second gate connection line segment 132B, and the first gate connection line segment 132A and the second gate connection line segment 132B are located at different positions, so as to ensure an effective electrical connection between the gate electrode 122 and the gate connection line 132. Specifically, the first gate connection line segment 132A extends along the first direction X and is electrically connected to the plurality of gate electrodes 122, and the second gate connection line segment 132B extends along the second direction Y and is electrically connected to the plurality of first gate connection line segments 132A.

On the plane where the substrate 110 is located, the vertical projection of the gate connection line 132 partially overlaps with the vertical projection of the source connection line 1311 or the drain connection line 1312. Specifically, along the second direction Y, the first gate connection line segment 132A and one of the first source connection line segment 1311A or the first drain connection line segment 1312A are distributed on a same side of the active region aa. As shown in FIG. 1, the first source connection line segment 1311A and the first gate connection line segment 132A are located on a same side of a same active region aa, or the first drain connection line segment 1312A and the first gate connection line segment 132A are located on a same side of a same active region aa. Along the first direction X, the second gate connection line segment 132B and one of the second source connection line segment 1311B or the second drain connection line segment 1312B are distributed on a same side of a plurality of active regions aa. As shown in FIG. 1, the second source connection line segment 1311B and the second gate connection line segment 132B are located on a same side of a plurality of active regions aa. A relative position of the source connection line 1311 and the gate connection line 132 and a relative position of the drain connection line 1312 and the gate connection line 132 are set, effectively ensuring that the source connection line 1311 and the drain connection line 1312 are not in contact with each other and do not overlap with each other, and further avoiding generation of a parasitic capacitance. Continuing to refer to FIG. 2 and FIG. 3, on the plane where the substrate 110 is located, the vertical projection of the gate connection line 132 partially overlaps with the vertical projection of the source connection line 1311, and the gate connection line 132 and the source connection line 1311 are disposed in different layers; or on the plane where the substrate 110 is located, the vertical projection of the gate connection line 132 partially overlaps with the vertical projection of the drain connection line 1312, and the gate connection line 132 and the drain connection line 1312 are disposed in different layers.

Since on the plane where the substrate 110 is located, the vertical projection of the gate connection line 132 partially overlaps with the vertical projection of the source connection line 1311, or on the plane where the substrate 110 is located, the vertical projection of the gate connection line 132 partially overlaps with the vertical projection of the drain connection line 1312, in order to avoid a short circuit between a gate signal and a source signal or a short circuit between a gate signal and a drain signal, the gate connection line 132 and one of the source connection line 1311 or the drain connection line 1312 may be disposed in different layers, so as to ensure a normal operation of the semiconductor device.

With continued reference to FIGS. 2 and 3, the source connection line 1311 and the drain connection line 1312 are disposed in a same layer.

Exemplarily, the source connection line 1311 and the drain connection line 1312 are disposed in a same layer, ensuring a simple structure of the semiconductor device and a simple structure of a film layer, and further facilitating to achieve a lightweight and thinness of the semiconductor device. Further, the source connection line 1311 and the drain connection line 1312 may be prepared by using a same material in a same process, ensuring a simple structure of the semiconductor device.

With continued reference to FIG. 2, the first dielectric layer a includes a first sub-dielectric layer a1 and a second sub-dielectric layer a2 that are stacked, and the first sub-dielectric layer a1 is located on a side, close to the substrate 110, of the second sub-dielectric layer a2. The gate connection line 132 is located on a side, away from the substrate 110, of the first sub-dielectric layer a1, and the source connection line 1311 and the drain connection line 1312 are located on a side, away from the substrate 110, of the second sub-dielectric layer a2. It can be understood that, compared with the source connection line 1311 and the drain connection line 1312, the gate connection line 132 is closer to the substrate 110. The source connection line 1311 and the gate connection line 132 are designed at different height positions, and the drain connection line 1312 and the gate connection line 132 are designed at different height positions, so as to achieve electrical insulation between each other, avoiding short circuits.

With continued reference to FIG. 2, the epitaxial structure 150 at least includes a channel layer 153 and a barrier layer 154, and a heterojunction structure is formed between the channel layer 153 and the barrier layer 154.

A material of the channel layer 153 may be GaN or other semiconductor materials, such as InAlN. The barrier layer 154 is located above the channel layer 153, and the barrier layer 154 may be any semiconductor material capable of forming the heterojunction structure with the channel layer 153, which includes a gallium-based compound semiconductor material or a nitrogen-based compound semiconductor material, such as InxAlyGazN_{1-x-y-z}, where 0≤x≤1, 0≤y≤1, and 0≤z≤1. A semiconductor heterojunction structure is composed by the channel layer 153 and the barrier layer 154, and the two-dimensional electron gas 155 is formed at an interface between the channel layer 153 and the barrier layer 154. The epitaxial structure 150 includes a nucleation layer 151, a buffer layer 152, the channel layer 153 and the barrier layer 154.

As shown in FIG. 2, the nucleation layer 151 is located on the substrate 110; the buffer layer 152 is located on a side, away from the substrate 110, of the nucleation layer 151; the channel layer 153 is located on a side, away from the nucleation layer 151, of the buffer layer 152; and the barrier layer 154 is located on a side, away from the buffer layer 152, of the channel layer 153. A heterojunction is formed by the barrier layer 154 and the channel layer 153, and the the two-dimensional electron gas 155 is formed at an interface of the heterojunction.

Exemplarily, materials of the nucleation layer 151 and the buffer layer 152 may be nitride, specifically GaN or AlN or other nitride, and the nucleation layer 151 and the buffer layer 152 may be used for matching the material of the substrate 110 and a material of the epitaxial channel layer 153.

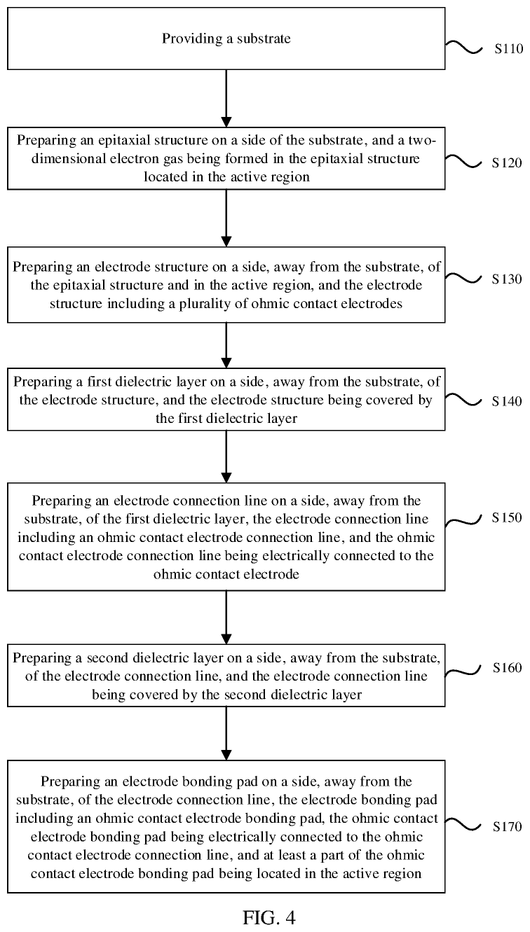

Based on a same concept, an embodiment of the present application further provides a method for manufacturing a semiconductor device, which is used for manufacturing the semiconductor device according to any one of the above embodiments, the semiconductor device includes an active region, and FIG. 4 is a flowchart of a method for manufacturing a semiconductor device according to an embodiment of the present application. As shown in FIG. 4, the method for manufacturing the semiconductor device includes steps S110 to S170.

S110: providing a substrate.

Exemplarily, a material of the substrate may be Si, SiC, gallium nitride or sapphire, or may be other materials suitable for growing gallium nitride. A method for preparing the substrate may be an atmospheric pressure chemical vapor deposition method, a sub-atmospheric pressure chemical vapor deposition method, a metal-organic compound vapor deposition method, a low pressure chemical vapor deposition method, or a high density plasma chemical vapor deposition method, and the like.

S120: preparing an epitaxial structure on a side of the substrate, and a two-dimensional electron gas being formed in the epitaxial structure located in the active region.

Exemplarily, a growth method of the epitaxial structure includes a metal organic chemical vapor deposition, a hydride vapor phase epitaxy, a molecular beam epitaxy, or a liquid phase epitaxy, and the like, which is not limited in the embodiments of the present application. The epitaxial layer may include a nucleation layer, a buffer layer, a channel layer, and a barrier layer, and the nucleation layer, the buffer layer, the channel layer, and the barrier layer are sequentially disposed on the side of the substrate. A semiconductor heterojunction structure is formed by the channel layer and the barrier layer, and the two-dimensional electron gas is formed at an interface between the channel layer and the barrier layer.

S130: preparing an electrode structure on a side, away from the substrate, of the epitaxial structure and in the active region, and the electrode structure including a plurality of ohmic contact electrodes.

Exemplarily, the ohmic contact electrode includes a source electrode and a drain electrode, and may be made of a conductive metal material such as titanium, aluminum, nickel, or gold. An ohmic contact is formed by the ohmic contact electrode and a surface of the substrate.

S140: preparing a first dielectric layer on a side, away from the substrate, of the electrode structure, and the electrode structure being covered by the first dielectric layer.

Exemplarily, the first dielectric layer may be made of a material such as silicon dioxide, silicon nitride, or aluminum oxide. A method for preparing the first dielectric layer includes a physical vapor deposition or a chemical vapor deposition.

S150: preparing an electrode connection line on a side, away from the substrate, of the first dielectric layer, the electrode connection line including an ohmic contact electrode connection line, and the ohmic contact electrode connection line being electrically connected to the ohmic contact electrode.

Exemplarily, the electrode connection line may be made of a conductive metal such as aluminum, nickel, gold, silver, or platinum.

S160: preparing a second dielectric layer on a side, away from the substrate, of the electrode connection line, and the electrode connection line being covered by the second dielectric layer.

Exemplarily, the second dielectric layer may be made of a material such as silicon dioxide, silicon nitride, or aluminum oxide. Similarly, a method for preparing the second dielectric layer includes a physical vapor deposition or a chemical vapor deposition.

S170: preparing an electrode bonding pad on a side, away from the substrate, of the electrode connection line, the electrode bonding pad including an ohmic contact electrode bonding pad, the ohmic contact electrode bonding pad being electrically connected to the ohmic contact electrode connection line, and at least a part of the ohmic contact electrode bonding pad being located in the active region.

Exemplarily, due to an existence of the electrode connection line, a design of the electrode bonding pad is relatively flexible, and is not limited by a structure of an electrode. A relatively large area of the electrode bonding pad may be located in the active region, so that a parasitic capacitance formed by the electrode bonding pad and a semiconductor structure in the substrate is reduced, and an area of a device is also reduced to improve an integration level. A size of the electrode bonding pad may be changed by requirements for later package.

According to the method for manufacturing the semiconductor device provided by the embodiments of the present application, an electrical connection between the electrode structure and the electrode bonding pad is realized by means of the electrode connection line, ensuring a flexible arrangement of the electrode bonding pad; further, the at least a part of the ohmic contact electrode bonding pad is disposed in the active region, so that a parasitic capacitance between the at least a part of the ohmic contact electrode bonding pad and the substrate is shielded by the two-dimensional electron gas in a heterojunction structure, reducing the parasitic capacitance between the ohmic contact electrode bonding pad and the substrate, and further satisfying increasingly high requirements on an input capacitance and an output capacitance of a semiconductor device; meanwhile, the at least a part of the ohmic contact electrode bonding pad is disposed in the active region, so that an area of the inactive region may be greatly reduced, reducing an overall area of a semiconductor device and improving an integration level of a semiconductor device, and further facilitating a miniaturization design of a semiconductor device while reducing a cost of a chip.

It is noted that the foregoing are merely preferred embodiments of the present application and applied technical principles. Those skilled in the art may understand that the present application is not limited to the specific embodiments described herein, and it is possible for those skilled in the art to make various obvious changes, readjustments and replacements without departing from the scope of protection of the present application. Therefore, although the present application is described in detail through the above embodiments, the present application is not limited to the above embodiments, and more other equivalent embodiments may be included without departing from the concept of the present application, and the scope of the present application is determined by the scope of the appended claims.

What is claimed is:

1. A semiconductor device, comprising an active region, and the semiconductor device further comprising:
a substrate;
an epitaxial structure located on a side of the substrate, and a two-dimensional electron gas being formed in the epitaxial structure located in the active region;
an electrode structure located on a side, away from the substrate, of the epitaxial structure and located in the active region, and the electrode structure comprising a plurality of ohmic contact electrodes;
a first dielectric layer located on a side, away from the substrate, of the electrode structure, and the electrode structure being covered by the first dielectric layer;
an electrode connection line located on a side, away from the substrate, of the first dielectric layer, the electrode connection line comprising an ohmic contact electrode connection line, and the ohmic contact electrode connection line being electrically connected to the plurality of ohmic contact electrodes;
a second dielectric layer located on a side, away from the substrate, of the electrode connection line, and the electrode connection line being covered by the second dielectric layer; and
an electrode bonding pad located on a side, away from the substrate, of the second dielectric layer, the electrode bonding pad comprising an ohmic contact electrode bonding pad, the ohmic contact electrode bonding pad being electrically connected to the ohmic contact electrode connection line, and at least a part of the ohmic contact electrode bonding pad being located in the active region.

2. The semiconductor device according to claim 1, wherein the plurality of ohmic contact electrodes comprise at least one source electrode and at least one drain electrode;
the ohmic contact electrode connection line comprises a source connection line and a drain connection line, the source connection line is electrically connected to the at least one source electrode, and the drain connection line is electrically connected to the at least one drain electrode;
the ohmic contact electrode bonding pad comprises a source bonding pad and a drain bonding pad, the source bonding pad is electrically connected to the source connection line, and the drain bonding pad is electrically connected to the drain connection line; and
on a plane where the substrate is located, a vertical projection of the source connection line is located outside a vertical projection of the drain connection line.

3. The semiconductor device according to claim 2, wherein the at least one source electrode comprises a plurality of source electrodes, the at least one drain electrode comprises a plurality of drain electrodes, the active region is provided with the plurality of source electrodes and the plurality of drain electrodes, the plurality of source electrodes are arranged along a first direction, each of the plurality of source electrodes extends along a second direction, the plurality of drain electrodes are arranged along the first direction, each of the plurality of drain electrodes extends along the second direction, and the first direction and the second direction intersect and are both parallel to the plane where the substrate is located;
the source connection line comprises a plurality of first source connection line segments and a second source connection line segment, the plurality of first source connection line segments are electrically connected to the plurality of source electrodes, and the second source connection line segment is electrically connected to the plurality of first source connection line segments; and
the drain connection line comprises a plurality of first drain connection line segments and a second drain connection line segment, the plurality of first drain connection line segments are electrically connected to the plurality of drain electrodes, and the second drain connection line segment is electrically connected to the plurality of first drain connection line segments.

4. The semiconductor device according to claim 3, wherein the active region comprises a plurality of active region groups sequentially disposed along the second direction, and each of the plurality of active region groups comprises a first active region and a second active region disposed along the second direction;
along the second direction, each of the plurality of first source connection line segments and each of the plurality of first drain connection line segments are located on two opposite sides of one of the first active region or the second active region in a same active region group; and
along the first direction, the second source connection line segment and the second drain connection line segment are located on two opposite sides of the plurality of active region groups.

5. The semiconductor device according to claim 3, wherein the active region comprises a plurality of active region groups sequentially disposed along the second direction, and each of the plurality of active region groups comprises a first active region and a second active region disposed along the second direction;
each of the plurality of first source connection line segments is located between the first active region and the second active region in a same active region group, the plurality of source electrodes in the first active region and the second active region in a same active region group are all electrically connected to the first source connection line segment, and in a same active region group, the plurality of drain electrodes in the first active region and the plurality of drain electrodes in the second active region are electrically connected to different first drain connection line segments, respectively; and
each of the plurality of first drain connection line segments is located between the first active region in one active region group and the second active region in another active region group disposed adjacently to the one active region group along the second direction, the plurality of drain electrodes in the first active region in one active region group and the second active region in another active region group disposed adjacently to the one active region group along the second direction are all electrically connected to the first drain connection line segment, and the plurality of source electrodes in the first active region in one active region group and the plurality of source electrodes in the second active region in another active region group disposed adjacently to the one active region group along the second direction are electrically connected to different first source connection line segments, respectively.

6. The semiconductor device according to claim 3, wherein the active region comprises a plurality of active region groups sequentially disposed along the second direction, and each of the plurality of active region groups comprises a first active region and a second active region disposed along the second direction;
each of the plurality of first drain connection line segments is located between the first active region and the second active region in a same active region group, the plurality of drain electrodes in the first active region and the second active region in a same active region group are all electrically connected to the first drain connection line segment, and in a same active region group, the plurality of source electrodes in the first active region and the plurality of source electrodes in the second active region are electrically connected to different first source connection line segments, respectively; and
each of the plurality of first source connection line segments is located between the first active region in one active region group and the second active region in another active region group disposed adjacently to the one active region group along the second direction, the plurality of source electrodes in the first active region in one active region group and the second active region in another active region group disposed adjacently to the one active region group along the second direction are all electrically connected to the first source connection line segment, and the plurality of drain electrodes in the first active region in one active region group and the plurality of drain electrodes in the second active region in another active region group disposed adjacently to the one active region group along the second direction are electrically connected to different first drain connection line segments, respectively.

7. The semiconductor device according to claim 3, wherein the active region comprises a plurality of active region groups sequentially disposed along the second direction, and each of the plurality of active region groups comprises a first active region and a second active region disposed along the second direction;
the semiconductor device further comprises an inactive region surrounding the active region;
along the second direction, each of the plurality of first source connection line segments and each of the plurality of first drain connection line segments are located in the inactive region on two sides of one of the first active region or the second active region in a same active region group; and
along the first direction, the second source connection line segment and the second drain connection line segment are located in the inactive region on two sides of the plurality of active region groups.

8. The semiconductor device according to claim 2, wherein the electrode structure further comprises at least one gate electrode;
the electrode connection line further comprises a gate connection line, and the gate connection line is electrically connected to the at least one gate electrode; and
the electrode bonding pad further comprises a gate bonding pad, the gate bonding pad is electrically connected to the gate connection line, and at least a part of the gate bonding pad is located in the active region.

9. The semiconductor device according to claim 8, wherein on the plane where the substrate is located, a vertical projection of the gate connection line partially overlaps with the vertical projection of the source connection line.

10. The semiconductor device according to claim 8, wherein on the plane where the substrate is located, a vertical projection of the gate connection line partially overlaps with the vertical projection of the drain connection line.

11. The semiconductor device according to claim 8, wherein the at least one source electrode comprises a plurality of source electrodes, the at least one drain electrode comprises a plurality of drain electrodes, the at least one gate electrode comprises a plurality of gate electrodes, the active region is provided with the plurality of source electrodes, the plurality of gate electrodes and the plurality of drain electrodes, the plurality of source electrodes are arranged along a first direction, each of the plurality of source electrodes extends along a second direction, the plurality of gate electrodes are arranged along the first direction, each of the plurality of gate electrodes extends along the second direction, the plurality of drain electrodes are arranged along the first direction, each of the plurality of drain electrodes extends along the second direction, the gate electrode is located between the source electrode and the drain electrode along the first direction, and the first direction and the second direction intersect and are both parallel to the plane where the substrate is located;
the source connection line comprises a plurality of first source connection line segments and a second source connection line segment, the plurality of first source connection line segments are electrically connected to the plurality of source electrodes, and the second source connection line segment is electrically connected to the plurality of first source connection line segments;
the gate connection line comprises a plurality of first gate connection line segments and a second gate connection line segment, the plurality of first gate connection line segments are electrically connected to the plurality of gate electrodes, and the second gate connection line segment is electrically connected to the plurality of first gate connection line segments; and
the drain connection line comprises a plurality of first drain connection line segments and a second drain connection line segment, the plurality of first drain connection line segments are electrically connected to the plurality of drain electrodes, and the second drain connection line segment is electrically connected to the plurality of first drain connection line segments.

12. The semiconductor device according to claim 11, wherein the active region comprises a plurality of active region groups sequentially disposed along the second direction, and each of the plurality of active region groups comprises a first active region and a second active region disposed along the second direction; and
along the second direction, each of the plurality of first source connection line segments and each of the plurality of first gate connection line segments are located on a same side of one of the first active region or the second active region in a same active region group.

13. The semiconductor device according to claim 11, wherein the active region comprises a plurality of active region groups sequentially disposed along the second direction, and each of the plurality of active region groups comprises a first active region and a second active region disposed along the second direction; and
along the second direction, each of the plurality of first drain connection line segments and each of the plurality of first gate connection line segments are located on a same side of one of the first active region or the second active region in a same active region group.

14. The semiconductor device according to claim 11, wherein the active region comprises a plurality of active region groups sequentially disposed along the second direction, and each of the plurality of active region groups comprises a first active region and a second active region disposed along the second direction; and
along the first direction, the second source connection line segment and the second gate connection line segment are located on a same side of the plurality of active region groups.

15. The semiconductor device according to claim 11, wherein the active region comprises a plurality of active region groups sequentially disposed along the second direction, and each of the plurality of active region groups comprises a first active region and a second active region disposed along the second direction; and
along the first direction, the second drain connection line segment and the second gate connection line segment are located on a same side of the plurality of active region groups.

16. The semiconductor device according to claim 11, wherein on the plane where the substrate is located, a vertical projection of the gate connection line partially overlaps with the vertical projection of the source connection line, and the gate connection line and the source connection line are disposed in different layers.

17. The semiconductor device according to claim 11, wherein on the plane where the substrate is located, a vertical projection of the gate connection line partially overlaps with the vertical projection of the drain connection line, and the gate connection line and the drain connection line are disposed in different layers.

18. The semiconductor device according to claim 11, wherein the source connection line and the drain connection line are disposed in a same layer.

19. The semiconductor device according to claim 18, wherein the first dielectric layer comprises a first sub-dielectric layer and a second sub-dielectric layer that are stacked, and the first sub-dielectric layer is located on a side, close to the substrate, of the second sub-dielectric layer; and
the gate connection line is located on a side, away from the substrate, of the first sub-dielectric layer, and the source connection line and the drain connection line are located on a side, away from the substrate, of the second sub-dielectric layer.

20. A method for manufacturing a semiconductor device, comprising:
providing a substrate;
preparing an epitaxial structure on a side of the substrate, and a two-dimensional electron gas being formed in the epitaxial structure located in an active region of the semiconductor device;
preparing an electrode structure on a side, away from the substrate, of the epitaxial structure and in the active region, and the electrode structure comprising a plurality of ohmic contact electrodes;
preparing a first dielectric layer on a side, away from the substrate, of the electrode structure, and the electrode structure being covered by the first dielectric layer;
preparing an electrode connection line on a side, away from the substrate, of the first dielectric layer, the electrode connection line comprising an ohmic contact electrode connection line, and the ohmic contact electrode connection line being electrically connected to the plurality of ohmic contact electrodes;
preparing a second dielectric layer on a side, away from the substrate, of the electrode connection line, and the electrode connection line being covered by the second dielectric layer; and
preparing an electrode bonding pad on a side, away from the substrate, of the electrode connection line, the electrode bonding pad comprising an ohmic contact electrode bonding pad, the ohmic contact electrode bonding pad being electrically connected to the ohmic contact electrode connection line, and at least a part of the ohmic contact electrode bonding pad being located in the active region.
